(19) United States
(12) Patent Application Publication
(10) Pub. No.: US 2022/0216140 A1
(43) Pub. Date: Jul. 7, 2022

(54) INTEGRATED CIRCUIT CAPACITANCE DEVICE AND METHOD FOR MANUFACTURING INTEGRATED CIRCUIT CAPACITANCE DEVICE

(71) Applicant: CHANGXIN MEMORY TECHNOLOGIES, INC., Hefei City (CN)

(72) Inventors: Mengkang YU, Hefei (CN); Xingsong SU, Hefei (CN); Weiping BAI, Hefei (CN)

(73) Assignee: CHANGXIN MEMORY TECHNOLOGIES, INC., Hefei City (CN)

(21) Appl. No.: 17/445,970

(22) Filed: Aug. 26, 2021

Related U.S. Application Data
(63) Continuation of application No. PCT/CN2021/103556, filed on Jun. 30, 2021.

(30) Foreign Application Priority Data
Jan. 4, 2021 (CN) 202110004419.4

(51) Int. Cl. H01L 23/522; H01L 23/532; H01L 27/108

(52) U.S. Cl. CPC H01L 23/5222; H01L 27/10844; H01L 23/5329

(57) ABSTRACT

A method for manufacturing an integrated circuit capacitance device includes the following. A substrate is provided. A sacrificial layer and a support layer that are alternately laminated at an upper surface of the substrate are formed. A capacitance hole is formed within the support layer and the sacrificial layer. A lower electrode is formed at sidewalls and a bottom of the capacitance hole. The opening is formed on the support layer. The opening exposes the sacrificial layer, and the sacrificial layer is removed based on the opening. A laminated structure including dielectric layer structure and an interface layer that are alternately laminated is formed at a surface of the lower electrode. A heat treatment is performed on the laminated structure. An upper electrode is formed at a surface of the laminated structure.

### CROSS-REFERENCE TO RELATED APPLICATIONS

This is a continuation of International Application No. PCT/CN2021/103556 filed on Jun. 30, 2021, which claims priority to Chinese Patent Application No. 202110004419.4 filed on Jan. 4, 2021. The disclosures of these applications are hereby incorporated by reference in their entirety.

### BACKGROUND

A Dynamic Random Access Memory (DRAM) is a semiconductor storage device that is commonly used in the computer, which is composed of many repeated storage units. As the size of the capacitance of the DRAM is shrinks, the capacitance capacity is reduced in the premise of the same height. Therefore, selecting a dielectric material with a higher K value has become a main research direction, and the dielectric material with the higher K value needs to be heat treated to form a desired lattice structure. However, most of the ultra-thin and high K dielectric materials subjected to the heat treatment are deposited, and then a polycrystalline structure is generated with a large number of grain boundaries formed. The formation of the large number of grain boundaries will cause a large leakage current, and it is necessary to suppress the leakage.

### SUMMARY

The present disclosure relates generally to the field of semiconductor devices and manufacture, and more specifically to an integrated circuit capacitance device and a method for manufacturing an integrated circuit capacitance device.

The first aspect of the present disclosure provides a method for manufacturing an integrated circuit capacitance device. The method includes the following steps. A substrate is provided. The sacrificial layer and a support layer that are alternately laminated are formed at an upper surface of the substrate. A capacitance hole is formed within the support layer and the sacrificial layer. An lower electrode is formed at sidewalls and a bottom of the capacitance hole. An opening is formed on the support layer and the opening exposes the sacrificial layer. The sacrificial layer is removed based on the opening. An laminated structure including a dielectric layer structure and an interface layer that are alternately laminated is formed at a surface of the lower electrode. The dielectric layer structure includes a first dielectric material layer. The interface layer includes a second dielectric material layer that has a higher band gap energy than that of the first dielectric material layer. A heat treatment is performed on the laminated structure. The first dielectric material layer subjected to the heat treatment is in a crystalline phase and the second dielectric material layer subjected to the heat treatment is in an amorphous phase. An upper electrode is formed at a surface of the laminated structure. At least the interface layer is provided between the upper electrode or the lower electrode and the dielectric layer structure.

The second aspect of the present disclosure provides an integrated circuit capacitance device. The integrated circuit capacitance device includes a lower electrode an upper electrode, a dielectric layer structure between the lower electrode and the upper electrode, and an interface layer at least provided between the lower electrode or the upper electrode and the dielectric layer structure. The dielectric layer structure includes a first dielectric layer material layer. The interface layer includes a second dielectric material layer that has a higher band gap energy than that of the first dielectric material layer. The first dielectric material layer is in a crystalline phase and the second dielectric material layer is in an amorphous phase.

The third aspect of the present disclosure provides a memory. The memory includes the above integrated circuit capacitance device.

Details of the various embodiments of the present disclosure will be described in the following drawings and description. According to the specification, the drawings, and the claims, those skilled in the art will readily understand other features, solved problems, and beneficial effects of the present disclosure.

### BRIEF DESCRIPTION OF THE DRAWINGS

In order to better describe and explain the embodiments of the present disclosure, reference is made to one or more drawings, but additional details or examples for describing the drawings should not be construed as limiting the scope of any one of the present disclosure, currently described embodiments or preferred embodiments of the present disclosure.

FIG. 1 is a flowchart of a method for manufacturing an integrated circuit capacitance device according to embodiments of the present disclosure.

FIG. 2 is a schematic diagram showing a partial cross-sectional structure of a substrate according to embodiments of the present disclosure.

FIG. 3 is a schematic diagram showing a partial cross-sectional structure of the sacrificial layer and the support layer that are alternately laminated formed according to embodiments of the present disclosure.

FIG. 4 is a schematic diagram showing a partial cross-sectional structure of the capacitance hole formed according to embodiments of the present disclosure.

FIG. 5 is a schematic diagram showing a partial cross-sectional structure of the lower electrode formed according to some embodiments of the present disclosure.

FIG. 6 is a schematic structural diagram illustrating that the opening is formed on support layer and then the sacrificial layer is removed according to some embodiments of the present disclosure, and illustrating a partial cross-sectional structure along the AA′ direction of FIG. 7.

FIG. 7 is a top view of a capacitance structure obtained after removing the sacrificial layer.

FIG. 8 is a schematic diagram showing a partial cross-sectional structure of the laminated structure formed according to some embodiments of the present disclosure.

FIG. 9 is a schematic diagram showing a partial cross-sectional structure that the third dielectric material layer is formed on the first dielectric material layer according to some embodiments of the present disclosure.

FIG. 10 is a schematic diagram showing a partial cross-sectional structure that the upper electrode is formed on the laminated structure according to some embodiments of the present disclosure.

FIG. 11 is a schematic diagram showing a partial cross-sectional structure that the upper electrode is formed on the laminated structures according to some embodiments of the present disclosure.

FIG. 12 is a schematic diagram showing a partial cross-sectional structure that the filling layer is formed at the upper electrode according to some embodiments of the present disclosure.

FIG. 13 is a schematic diagram showing a partial cross-sectional structure that the filling layer is formed at the upper electrode according to some embodiments of the present disclosure.

### DETAILED DESCRIPTION

In order to understand the present disclosure, the application will be further described with reference to the related drawings. The preferred embodiment of the present disclosure is given in the drawings. However, the present disclosure may be implemented in many different forms, and is not limited to the embodiments described herein. Conversely, the purpose of providing these embodiments is to make the understanding of the content of the present disclosure more thoroughly.

Unless otherwise defined, all technical and scientific terms used herein are the same as those skilled in the art of the present disclosure typically understand. The terms used in the specification of the present disclosure are for the purpose of describing particular embodiments only and are not intended to limit the application.

In the case of “comprising”, “having”, and “containing” described herein, other components may be included unless a clear defined language is used, such as “only”, “composed of only . . . ”. Unless mentioned to the contrary, terms in the singular may include the same terms in the plural, and the number thereof should not be regarded as one.

In order to illustrate the above technical solution of the present disclosure, the following will be described below by way of specific embodiments.

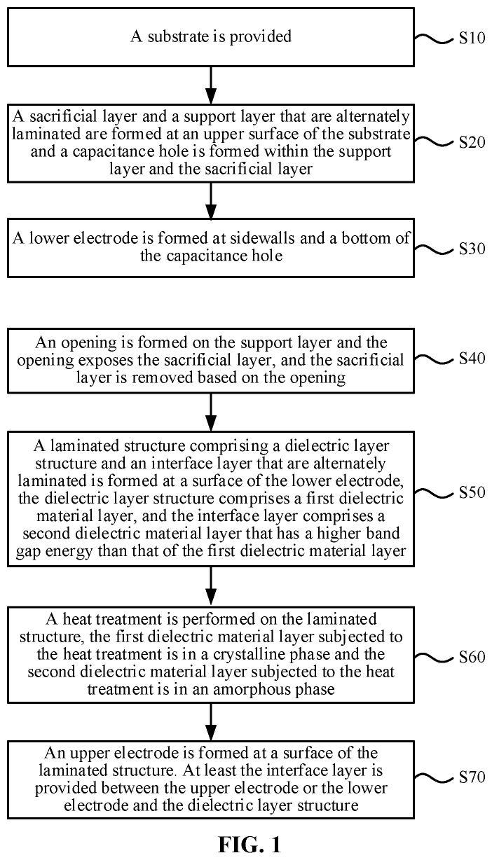

In a method for manufacturing an integrated circuit capacitance device provided in some embodiments of the present disclosure, as shown in FIG. 1, the method includes the following steps.

At step S10, a substrate is provided.

At step S20, a sacrificial layer and support layer that are alternately laminated are formed at an upper surface of the substrate and a capacitance hole is formed within the support layer and the sacrificial layer.

At step S30, a lower electrode is formed at sidewalls and a bottom of the capacitance hole.

At step S40, an opening is formed on the support layer and the opening exposes the sacrificial layer, and the sacrificial layer is removed based on the opening.

At step S50, the laminated structure including dielectric layer structure and an interface layer that are alternately laminated is formed at a surface of the lower electrode. The dielectric layer structure includes a first dielectric material layer, and the interface layer includes a second dielectric material layer that has a higher band gap energy than that of the first dielectric material layer.

At step S60, a heat treatment is performed on the laminated structure. The first dielectric material layer subjected to the heat treatment is in a crystalline phase and the second dielectric material layer subjected to the heat treatment is in an amorphous phase.

At step S70, an upper electrode is formed at a surface of the each laminated structure.

At least the interface layer is provided between the upper electrode or the lower electrode and the dielectric layer structure.

In the method of manufacturing the integrated circuit capacitance device provided in the above embodiment, after the steps of removing the sacrificial layer and forming the lower electrode, the laminated structure including the dielectric layer structure and the interface layer that are alternately laminated is formed at the surface of the lower electrode, and the heat treatment is performed on the formed laminated structure. The upper electrode is formed on the surface of the laminated structure, at least the interface layer is provided between the upper electrode or the lower electrode and the dielectric layer structure. The first dielectric material layer subjected to the heat treatment is in a crystalline phase and after the heat treatment, the second dielectric material layer that has a higher band gap energy than that of the first dielectric material layer is in an amorphous phase instead of a conventional barrier layer material alumina to ensure stable presence of the laminated structure subjected to the heat treatment, and the interface layer effectively avoids generation of an oxygen vacancy, which may effectively reduce a leakage current when using a high K value dielectric and enhance performance of the DRAM device.

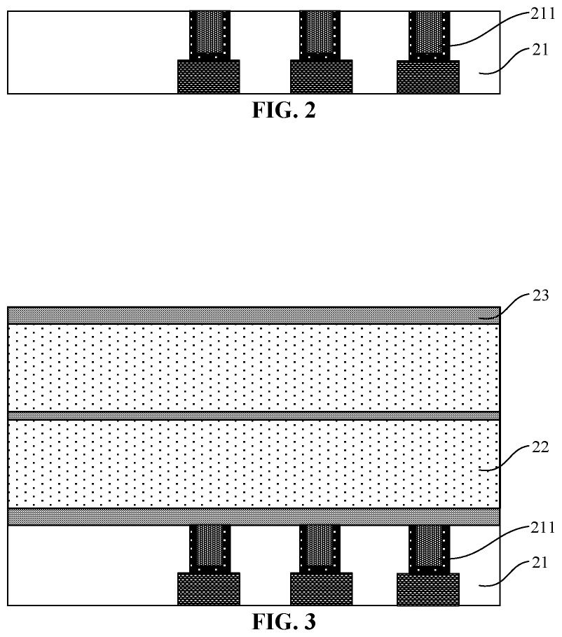

In some embodiments, as shown in FIG. 2, the substrate 21 is provided at step S10, the memory array structure is formed in the substrate 21, and the memory array structure includes a plurality of pads 211. The memory array structure also includes transistor Word lines and Bit lines, and the pad 211 is electrically connected to a transistor source within the memory array structure.

In some embodiments, the pads 211 may be, but are not limited to, an arrangement of a hexagonal array, and the arrangement correspond to an arrangement of the subsequent manufactured integrated circuit capacitance device.

In some embodiments, the pads 211 are isolated by a spacer layer, and a material of the spacer layer may be any one or combination of any two or more of the following: silicon nitride (SiN), silicon oxide (SiO₂), aluminum oxide (Al₂O₃). In this embodiment, SiN may be selected as the material of the spacer layer.

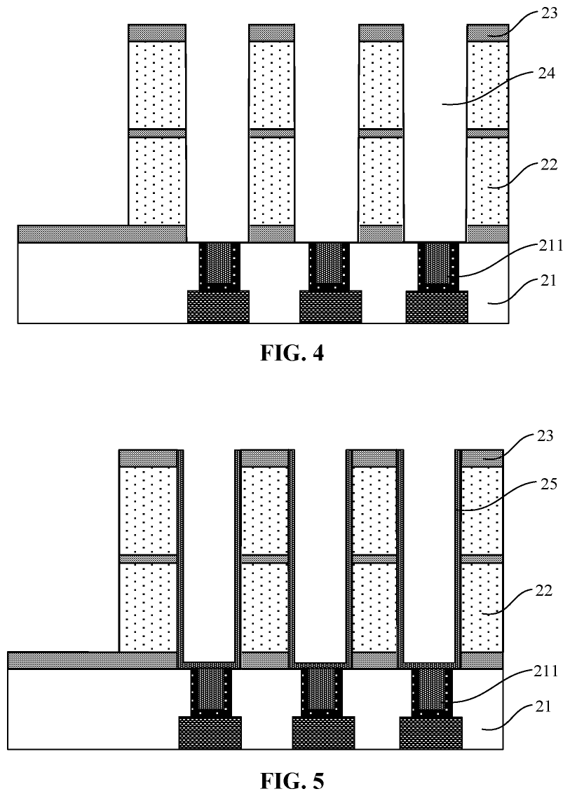

In some embodiments, as shown in FIG. 3 and FIG. 4, at step S20, the sacrificial layers 22 and support layer 23 that are alternately laminated are formed at an upper surface of the substrate 21, and a capacitance hole 24 is formed within the support layer 23 and the sacrificial layer 22.

In some embodiments, an Atomic Layer Deposition or a Chemical Vapor Deposition may be adopted to form the sacrificial layer 22 and the support layer 23.

In some embodiments, the material of the sacrificial layer 22 is different from that of the support layer, the etch rate of the sacrificial layer 22 is different from that of the support layer in the same etch process. Specifically, in the same etch process, the etch rate of the sacrificial layer 22 is far greater than that of the support layer, so that when the sacrificial layer 22 is completely removed, the support layer is almost completely preserved.

In some embodiments, polysilicon or silicon oxide may be selected as the material of the sacrificial layer, and silicon nitride may be selected as the material of the support layer.

In some embodiments, a photoresist may be formed as a mask layer at the upper surface of the sacrificial layer 22 and the support layer 23 that are alternately laminated. Of course, a mask layer of other materials (such as, a silicon nitride hard mask layer, etc.) may also be formed in other examples. Then, a photolithography process is adopted to pattern the mask layer to obtain a patterned mask layer configured to define the capacitance hole. Finally, a dry etch process, a wet etch process, or a process that combines the dry etch process and the wet etch process may be adopted to etch the support layer and the sacrificial layer 22 according to the patterned mask layer configured to define the capacitance hole, so that a capacitance hole 25 that penetrates from top to down is formed within the support layer and the sacrificial layer 22, and the capacitance hole 24 exposes a bottom pad 211.

In some embodiments, as shown in FIG. 5, at step S30, a lower electrode 25 is formed on the sidewalls and the bottom of the capacitance hole 24. In some embodiments, firstly, an Atomic Layer Deposition or a Chemical Vapor Deposition may be adopted to deposit the lower electrode 25 at the sidewalls and the bottom of the capacitance hole 24. Preferably, the lower electrode 25 includes a compound formed by one or two of metal nitride and metal silicide, such as Titanium Nitride, Titanium Silicide, Nickel Silicide, or Titanium Silicon Nitride (TiSixNy).

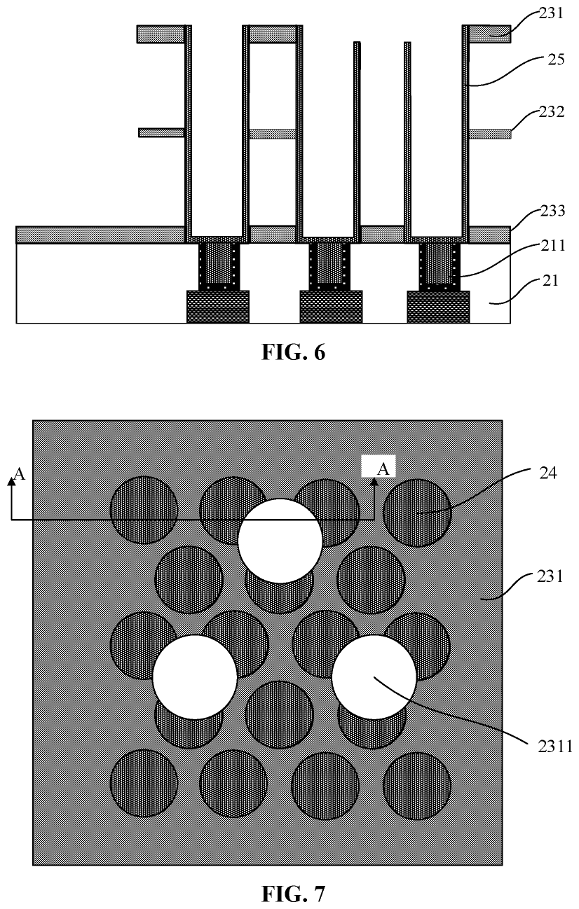

In some embodiments, as shown in FIG. 6, the support layer 23 includes a top support layer 231, an intermediate support layer 232, and a bottom support layer 233 that are successively laminated with intervals in an order from the top to bottom. The operation that the opening 2311 is formed on the support layer 23 and the opening exposes the sacrificial layer 22, and the sacrificial layer 22 is removed based on the opening 2311 at step 40 includes the following steps.

At step S41, a first opening within the top support layer is formed by etching the top support layer 231 based on the patterned mask layer. The first opening exposes sacrificial layer 22 between the top support layer 231 and the intermediate support layer 232.

At step S42, the sacrificial layer 22 between the top support layer 231 and the intermediate support layer 232 is removed based on the first opening.

At step S43, a second opening within the intermediate support layer 232 is formed based on the first opening. The second opening exposes the sacrificial layer 22 between the intermediate support layer 232 and the bottom support layer 233.

At step S44, the sacrificial layer 22 between the intermediate support layer 232 and the bottom support layer 233 is removed and a third opening within the bottom support layer 233 is formed.

In some embodiments, one opening 2311 overlaps only with one capacitance hole 24, or one opening 2311 overlaps with the plurality of capacitance holes 24 simultaneously, and the present disclosure is not limited to this. As shown in FIG. 7, FIG. 7 takes one opening 2311 overlapping with three capacitance holes 24 as an example.

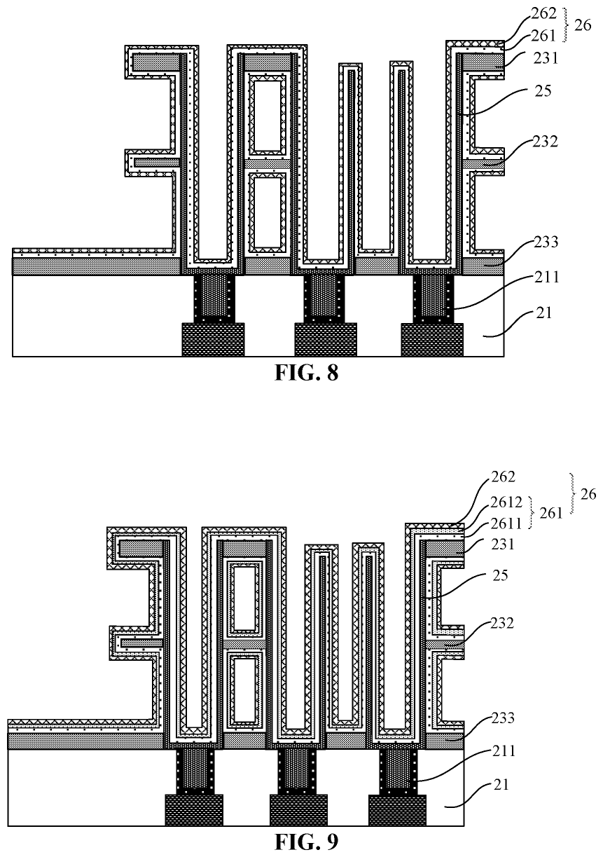

In some embodiments, as shown in FIG. 8, at step S50, the laminated structure 26 including dielectric layer structure 261 and interface layer 262 that are alternately laminated is formed at the surface of the lower electrode 25. The dielectric layer structure 261 includes a first dielectric material layer 2611, and the interface layer 262 includes a second dielectric material layer that has a higher band gap energy than that of the first dielectric material layer 2611. On the one hand, after the heat treatment is performed on the laminated structure, the interface layer with a manufacturing thickness of less than 1 nm is still in an amorphous form, which maintains a stable grain boundary blocking capability while passivates and suppresses the leakage current. On the other hand, compared with the first dielectric material layer, the interface layer has a higher band gap energy, which further effectively suppresses the leakage current and enhances performance of the DRAM device.

In some embodiments, a corresponding organic reactant or inorganic reactant may be adopted to manufacture the first dielectric material layer, which is a technique well known in the art, and details will not be described herein.

In some embodiments, the present disclosure is not limited to a primary growth position, as shown in FIG. 8, the dielectric layer structure 261 (i.e. the first dielectric material layer 2611) and the interface layer 262 are formed sequentially, or the interface layer 262 and the dielectric layer structure 261 are formed sequentially. Of course, it is not limited to this. For example, the formed laminated structure 26 may be the dielectric layer structure 261, the formed laminated structure 26 may be the interface layer 262, the formed laminated structure 26 may be the dielectric layer structure 261 or the interface layer 262, and formed laminated structure 26 may be the dielectric layer structure 261 and the interface layer 262, or the like.

In some embodiments, the heat treatment is performed on the laminated structure 26 including the dielectric layer structure 261 and the interface layer 262, and the temperature of the heat treatment is in a range from 500° C. to 900° C. In some embodiments, the temperature of the heat treatment may be 500° C., 600° C., 700° C., 800° C., or 900° C., or the like.

In some embodiments, a beryllium oxide layer (BeO), an indium oxide layer (In₂O₃), or a boron oxide layer (B₂O₃) is formed within each laminated structure 26 as the interface layer 262.

In some embodiments, the interface layer is formed by adopting the atomic deposition process. The deposition temperature is in a range from 200° C. to 500° C., and the deposition pressure is in a range from 0.1 torr to 0.6 torr. In some embodiments, the deposition temperature may be 200° C., 300° C., 400° C., or 500° C., or the like, and the deposition pressure may be 0.2 torr, 0.3 torr, 0.4 torr, 0.5 torr, or 0.6 torr, or the like. The reaction gases forming a beryllium oxide layer include dimethyl beryllium and water vapor. The boron oxide layer and the indium oxide layer may be manufactured by the atomic deposition process, and the process conditions are similar to the process parameters for manufacturing the beryllium oxide layer, the corresponding reaction gases may be adjusted according to synthetic conditions.

In some embodiments, a thickness of the interface layer 262 is in a range from 1 Å to 10 Å, and a band gap energy of the each interface layer 262 is greater than or equal to 6 eV. A thickness of the first dielectric material layer 2611 is in a range from 3 nm to 10 nm and a band gap energy of the first dielectric material layer 2611 is in a range from 3 eV to 6 eV. In some embodiments, the thickness of the each interface layer 262 may be 1 Å, 3 Å, 5 Å, 7 Å, 9 Å, or 10 Å, or the like, and a band gap energy of the each interface layer 262 may be 6 eV, 7 eV, 7.87 eV, 7.89 eV, 7.90 eV, 7.91 eV, 8 eV, or 9 eV, or the like. The thickness of the first dielectric material layer 2611 may be 3 nm, 5 nm, 7 nm, 9 nm, or 10 nm, or the like, and a band gap energy of the first dielectric material layer 2611 may be 3 eV, 4 eV, 5 eV, or 6 eV, or the like. The first dielectric material layer 2611 subjected to the heat treatment is in a crystalline phase and the second dielectric material layer subjected to the heat treatment is in an amorphous phase. The thickness of the interface layer should not be too thin, and should not be too thick. If the thickness of the interface layer is too thin, the effect of blocking the leakage current is deteriorated, and if the thickness of the interface layer is too thick, it is difficult to maintain an amorphous form when the heat treatment is performed on the laminated structure. Further, the first dielectric material layer needs a sufficient thickness, and when the heat treatment is performed on the laminated structure, the first dielectric material layer may form a crystalline phase, and the dielectric constant of the crystalline phase is higher. Compared with the first dielectric material layer, the second dielectric material layer that has a higher band gap energy may effectively reduce the leakage current generated by a higher K-value dielectric in the case of an external electric field, thereby enhancing the DRAM performance.

In some embodiments, as shown in FIG. 9, the method for manufacturing the integrated circuit capacitance device further includes following steps.

At step S51, under a condition of reducing gas atmosphere, a third dielectric material layer 2612 within the each dielectric layer structure 261 is formed at a surface of the first dielectric material layer 2611. The material of the third dielectric material layer 2612 at least comprises the material of the second dielectric material layer, which on the one hand may prevent the increase in crystal plane defects caused by oxidation of the surface of the first dielectric material layer, and may also increase the surface roughness of the first dielectric material layer so as to improve the adhesion between the third dielectric material layer and the first dielectric material layer.

It should be noted that the subsequently deposited upper electrode and the subsequently deposited filling layer are manufactured on the structures shown in FIG. 8 and FIG. 9, which merely used to elaborate the deposition of the upper electrode and the filling layer clearly, and it is not limited to this.

In some embodiments, the reducing gas atmosphere includes ammonia atmosphere, plasma nitridation atmosphere, or plasma oxidation atmosphere, and a treatment temperature of the reducing gas is in a range from 300° C. to 800° C. In some embodiments, the treatment temperature of the reducing gas may be 300° C., 400° C., 500° C., 600° C., 700° C., or 800° C., or the like.

In some embodiments, a thickness of the third dielectric material layer 2612 is in a range from 1 nm to 2 nm. In some embodiments, the thickness of the third dielectric material layer 2612 may be 1 nm, 1.2 nm, 1.4 nm, 1.6 nm, 1.8 nm, or 2 nm, or the like. The material of the third dielectric material layer includes any one or any combination of the following: tantalum oxide (Ta₂O₅), titanium oxide (TiO₂), niobium oxide (Nb₂O₅), aluminum oxide (Al₂O₃), silicon oxide (SiO₂), tin oxide (SnO₂), germanium oxide (GeO₂), molybdenum dioxide (MoO₂), molybdenum trioxide (MoO₃), iridium oxide (IrO₂), uthenium oxide (RuO₂), and the material of the third dielectric material layer at least comprises beryllium oxide (BeO), which on the one hand may effectively prevent the first dielectric material layer from leaking current, and on the other hand may increase interface adhesion at the boundary between the third dielectric material layer and a crystal plane of the second dielectric material layer, thereby suppressing leakage current caused by a large number of grain boundaries.

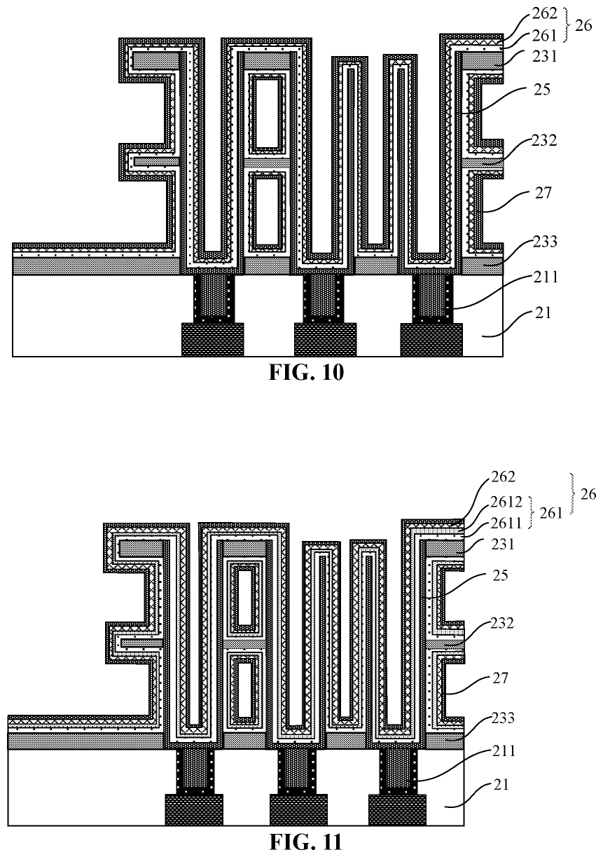

In some embodiments, as shown in FIG. 10 and FIG. 11, at step S70, the upper electrode 27 is formed at the surface of the laminated structure 26. At least interface layer 262 is provided between the upper electrode 27 or the lower electrode 25 and the dielectric layer structure 261.

In some embodiments, at least interface layer 262 being provided between the upper electrode 27 or the lower electrode 25 and the dielectric layer structure 261 includes the following two conditions. The interface layer 262 is provided between the upper electrode 27 and the dielectric layer structure 261, or the interface layer 262 is provided between the lower electrode 25 and the dielectric layer structure 261.

In some embodiments, the material of the upper electrode layer 27 may include one of tungsten, titanium, nickel, aluminum, platinum, titanium nitride, N-type polysilicon, P-type polysilicon, or a laminated layer formed by two or more in a group composed of the above materials.

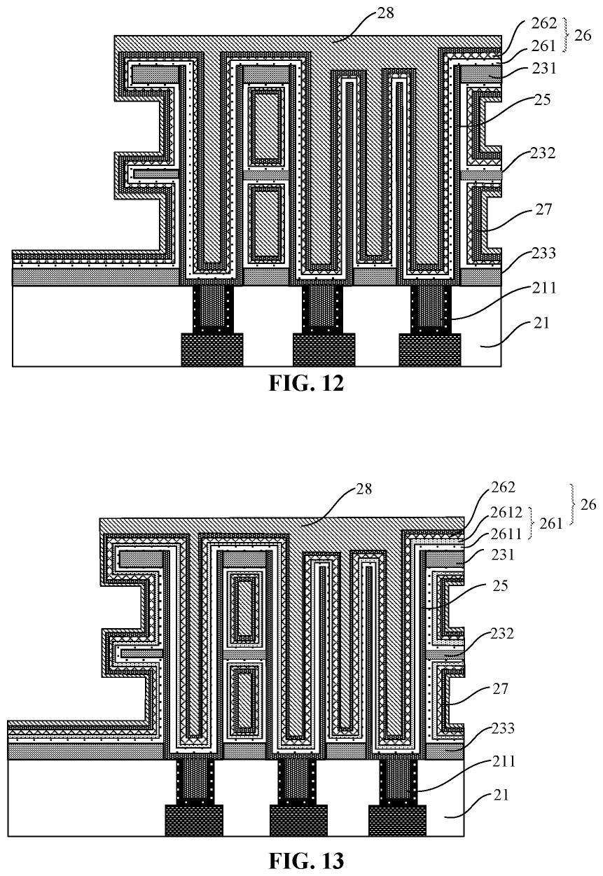

In some embodiments, as shown in FIG. 12 and FIG. 13, the method for manufacturing the integrated circuit capacitance device includes the following steps.

At S70, a filling layer 28 is formed at the surface of the upper electrode 27, and the filling layer 28 covers the upper electrode 27 and fills gaps between the upper electrodes 27.

In some embodiments, a low pressure chemical vapor deposition may be adopted, and a germanium source gas, a boron source gas, and a silicon source gas are simultaneously introduced into a furnace tube to perform a reaction to form the filling layer 28 at the outer surfaces of the upper electrode layer 27. The material of the filling layer 28 includes, but is not limited to, silicon germanium (SiGe), or the like.

Some embodiments of the present disclosure provide an integrated circuit capacitance device. Referring to FIG. 13, the capacitance device includes a lower electrode, an upper electrode, a dielectric layer structure between lower electrode and the upper electrode, and an interface layer at least provided between the lower electrode or the upper electrode and the dielectric layer structure. The dielectric layer structure includes a first dielectric material layer. The interface layer includes a second dielectric layer that has a higher band gap energy than that of the first dielectric material layer. The first dielectric material layer is in a crystalline phase and the second dielectric material layer is in an amorphous phase.

In some embodiments, the memory array structure is formed in the substrate 21 and the memory array structure includes a plurality of pads 211. The memory array structure also includes transistor Word lines and Bit lines, and the pad 211 is electrically connected to a transistor source within the memory array structure.

In some embodiments, the interface layer 262 includes a beryllium oxide layer, an indium oxide layer, or a boron oxide layer.

In some embodiments, the thickness of the interface layer 262 is in a range from 1 Å to 10 Å and the band gap energy of the interface layer 262 is greater than or equal to 6 eV. The thickness of the first dielectric material layer 2611 is in a range from 3 nm to 10 nm and the band gap energy of the first dielectric material layer 2611 is in a range from 3 eV to 6 eV. In some embodiments, the thickness of the interface layer 262 may be 1 Å, 3 Å, 5 Å, 7 Å, 9 Å, or 10 Å, or the like, and the band gap energy of the interface layer 262 may be 6 eV, 7 eV, 7.87 eV, 7.89 eV, 7.90 eV, 7.91 eV, 8 eV, or 9 eV, or the like. The thickness of the first dielectric material layer 2611 may be 3 nm, 5 nm, 7 nm, 9 nm, or 10 nm, or the like, and the band gap energy of the first dielectric material may be 3 eV, 4 eV, 5 eV, or 6 eV, or the like.

In some embodiments, the dielectric layer material 261 further includes a third dielectric material layer 2612. The third dielectric material layer is formed at a surface of the first dielectric material layer 2611, and the material of the third dielectric material layer 2612 at least comprises the material of the second dielectric material layer.

In some embodiments, continuing to refer to FIG. 12 and FIG. 13, the integrated circuit capacitance device further includes a filling layer 28 covering the upper electrode 27 and filling gaps between the upper electrodes 27.

Some embodiments of the present disclosure provide a memory. The memory includes the above-mentioned integrated circuit capacitance device.

It should be noted that the above-mentioned embodiments are for illustrative purpose only and not intended to limit the present disclosure.

Each of the embodiments in the specification is described in a progressive way, and each embodiment focuses on differences from other embodiments, the same or similar parts of each embodiment are referenced each other.

The various technical features of the above-mentioned embodiments may be arbitrarily combined. For brevity of description, not all of possible combinations of various technical features in the above-mentioned embodiments were described, however, as long as there is no contradiction in these technical features, it should be considered as the scope of this specification.

The above embodiments are merely expressed in several embodiments of the present disclosure, which are specific and detailed, but it should not to be construed as limiting the present disclosure. It should be pointed out that for those of ordinary skill in the art, several improvements and modifications can be made without departing from the principle of the present disclosure, and these improvements and modifications belong to the scope of protection of this application. Therefore, the protection scope of the present disclosure should be subject to the protection scope defined by the claims.

What is claimed is:

1. A method for manufacturing an integrated circuit capacitance device, comprising:
providing a substrate;
forming, at an upper surface of the substrate, a sacrificial layer and a support layer that are alternately laminated;
forming a capacitance hole within the support layer and the sacrificial layer;
forming a lower electrode at sidewalls and a bottom of the capacitance hole;
forming an opening on the support layer, wherein the opening exposes the sacrificial layer;
removing the sacrificial layer based on the opening;
forming, at a surface of the lower electrode, a laminated structure comprising a dielectric layer structure and an interface layer that are alternately laminated, wherein the dielectric layer structure comprises a first dielectric material layer, and the interface layer comprises a second dielectric material layer that has a higher band gap energy than that of the first dielectric material layer;
performing a heat treatment on the laminated structure, wherein the first dielectric material layer subjected to the heat treatment is in a crystalline phase and the second dielectric material layer subjected to the heat treatment is in an amorphous phase; and
forming an upper electrode at a surface of the laminated structure,
wherein at least the interface layer is provided between the upper electrode or the lower electrode and the dielectric layer structure.

2. The method for manufacturing the integrated circuit capacitance device of claim 1, wherein a beryllium oxide layer, a indium oxide layer, or a boron oxide layer is formed within the laminated structure as the interface layer.

3. The method for manufacturing the integrated circuit capacitance device of claim 2, wherein the interface layer is formed by adopting atomic deposition process, deposition temperature is in a range from 200° C. to 500° C., and deposition pressure comprises a range from 0.1 torr to 0.6 torr.

4. The method for manufacturing the integrated circuit capacitance device of claim 1, wherein a thickness of the interface layer is in a range from 1 Å to 10 Å, a band gap energy of the interface layer is greater than or equal to 6 eV, a thickness of the first dielectric material layer is in a range from 3 nm to 10 nm and a band gap energy of the first dielectric material layer is in a range from 3 eV to 6 eV.

5. The method for manufacturing the integrated circuit capacitance device of claim 1, further comprising:
under a condition of reducing gas atmosphere, forming a third dielectric material layer within the dielectric layer structure at a surface of the first dielectric material layer, wherein a material of the third dielectric material layer at least comprises a material of the second dielectric material layer.

6. The method for manufacturing the integrated circuit capacitance device of claim 5, wherein the reducing gas atmosphere comprises ammonia atmosphere, plasma nitridation atmosphere, or plasma oxidation atmosphere, and a treatment temperature of the reducing gas is in a range from 300° C. to 800° C.

7. The method for manufacturing the integrated circuit capacitance device of claim 5, wherein a thickness of the third dielectric material layer is in a range from 1 nm to 2 nm, the material of the third dielectric material layer comprises any one or any combination of the following: tantalum oxide, titanium oxide, niobium oxide, aluminum oxide, silicon oxide, tin oxide, germanium oxide, molybdenum dioxide, molybdenum trioxide, iridium oxide, uthenium oxide, and the material of the third dielectric material layer at least comprises beryllium oxide.

8. The method for manufacturing the integrated circuit capacitance device of claim 1, wherein the support layer comprises a top support layer, an intermediate support layer, and a bottom support layer that are successively laminated with intervals in an order from top to bottom, and forming the opening on the support layer, the opening exposing the sacrificial layer, and removing the sacrificial layer based on the opening comprises:
forming a patterned mask layer at an upper surface of the top support layer, wherein the patterned mask layer has a plurality of opening patterns, and the opening patterns define a shape and a position of the opening;
forming a first opening within the top support layer by etching the top support layer based on the patterned mask layer, wherein the first opening exposes sacrificial layer between the top support layer and the intermediate support layer;
removing the sacrificial layer between the top support layer and the intermediate support layer based on the first opening;
forming a second opening within the intermediate support layer based on the first opening, wherein the second opening exposes sacrificial layer between the intermediate support layer and the bottom support layer;
removing the sacrificial layer between the intermediate support layer and the bottom support layer; and
forming a third opening within the bottom support layer.

9. The method for manufacturing the integrated circuit capacitance device of claim 1, after said forming the upper electrode, further comprising: a step of forming a filling layer at a surface of the upper electrode, wherein the filling layer covers the upper electrode and fills gaps between upper electrodes.

10. An integrated circuit capacitance device, comprising:
a lower electrode;
an upper electrode;
a dielectric layer structure between the lower electrode and the upper electrode, and
an interface layer at least provided between the upper electrode or the each lower electrode and the dielectric layer structure;
wherein the dielectric layer structure comprises a first dielectric material layer, the interface layer comprises a second dielectric material layer that has a higher band gap energy than that of the first dielectric material layer, the first dielectric material layer is in a crystalline phase and the second dielectric material layer is in an amorphous phase.

11. The integrated circuit capacitance device of claim 10, wherein the interface layer comprises a beryllium oxide layer, a indium oxide layer, or a boron oxide layer.

12. The integrated circuit capacitance device of claim 10, wherein a thickness of the interface layer is in a range from 1 Å to 10 Å, a band gap energy of the interface layer is greater than or equal to 6 eV, a thickness of the first dielectric material layer is in a range from 3 nm to 10 nm and a band gap energy of the first dielectric material layer is in a range from 3 eV to 6 eV.

13. The integrated circuit capacitance device of claim 10, wherein the dielectric layer structure further comprises a third dielectric material layer, wherein the third dielectric material layer is formed at a surface of the first dielectric material layer, and a material of the third dielectric material layer at least comprises a material of the second dielectric material layer.

14. The integrated circuit capacitance device of claim 10, further comprising:
a filling layer covering the upper electrode and filling gaps between upper electrodes.

15. A memory, wherein the memory comprises an integrated circuit capacitance device comprising:
a lower electrode;
an upper electrode;
a dielectric layer structure between the lower electrode and the upper electrode, and
an interface layer at least provided between the upper electrode or the each lower electrode and the dielectric layer structure;
wherein the dielectric layer structure comprises a first dielectric material layer, the interface layer comprises a second dielectric material layer that has a higher band gap energy than that of the first dielectric material layer, the first dielectric material layer is in a crystalline phase and the second dielectric material layer is in an amorphous phase.

16. The memory of claim 15, wherein the interface layer comprises a beryllium oxide layer, a indium oxide layer, or a boron oxide layer.

17. The memory of claim 15, wherein a thickness of the interface layer is in a range from 1 Å to 10 Å, a band gap energy of the interface layer is greater than or equal to 6 eV, a thickness of the first dielectric material layer is in a range from 3 nm to 10 nm and a band gap energy of the first dielectric material layer is in a range from 3 eV to 6 eV.

18. The memory of claim 15, wherein the dielectric layer structure further comprises a third dielectric material layer, wherein the third dielectric material layer is formed at a surface of the first dielectric material layer, and a material of the third dielectric material layer at least comprises a material of the second dielectric material layer.

19. The memory of claim 15, wherein the integrated circuit capacitance device further comprises:
a filling layer covering the upper electrode and filling gaps between upper electrodes.
